(19) United States
(12) Patent Application Publication
(10) Pub. No.: US 2025/0095973 A1
(43) Pub. Date: Mar. 20, 2025

(54) Plasma Processing Apparatus and Method for Measuring Resonance Frequency

(71) Applicants: Tokyo Electron Limited, Tokyo (JP); The University of Shiga Prefecture, Shiga (JP)

(72) Inventors: Kazushi KANEKO, Yamanashi (JP); Eiki KAMATA, Yamanashi (JP); Osamu SAKAI, Shiga (JP)

(21) Appl. No.: 18/967,551

(22) Filed: Dec. 3, 2024

Related U.S. Application Data
(63) Continuation of application No. PCT/JP2023/021084, filed on Jun. 7, 2023.

(30) Foreign Application Priority Data
Jun. 9, 2022 (JP) 2022-093512

(51) Int. Cl. H01J 37/32

(52) U.S. Cl. CPC H01J 37/32935; H01J 37/32229; H01J 37/32256; H01J 37/32284; H01J 37/32311

(57) ABSTRACT

A plasma processing apparatus comprising: a processing chamber; an electromagnetic wave generator; a resonating structure formed by arranging resonators that are capable of resonating with a magnetic field component of electromagnetic waves; a measurement part configured to measure, for each frequency, a power of the electromagnetic waves traveling from the electromagnetic wave generator to the resonating structure and a power of transmitted waves, reflected waves, or scattered waves of the electromagnetic waves in the resonating structure; and a controller that performs measuring the power of the electromagnetic waves and the power of the transmitted waves, the reflected waves, or the scattered waves with the measurement part, and calculating a resonance frequency of the resonating structure based on frequency distribution of characteristic values of the resonating structure, calculated from the power of the electromagnetic waves and the power of the transmitted waves, the reflected waves, or the scattered waves.

### CROSS-REFERENCE TO RELATED APPLICATIONS

This application is a bypass continuation application of International Application No. PCT/JP2023/021084 having an international filing date of Jun. 7, 2023 and designating the United States, the International Application being based upon and claiming the benefit of priority from the Japanese Patent Application No. 2022-093512 filed on Jun. 9, 2022, the entire contents of which are incorporated herein by reference.

### TECHNICAL FIELD

The present disclosure relates to a plasma processing apparatus and a method for measuring a resonance frequency of a resonating structure in the plasma processing apparatus.

### BACKGROUND

Japanese Laid-open Patent Publication No. 2009-245593 discloses a plasma processing apparatus that produced plasma by supplying microwaves for plasma excitation into a processing chamber.

### SUMMARY

The present disclosure provides a technique for stably increasing a density of plasma by resonance.

According to an aspect of the disclosure, a plasma processing apparatus comprising: a processing chamber that provides a processing space where plasma processing is performed; an electromagnetic wave generator configured to generate electromagnetic waves to be supplied to the processing space; a resonating structure disposed in the processing chamber and formed by arranging a plurality of resonators that are capable of resonating with a magnetic field component of the electromagnetic waves and have sizes smaller than a wavelength of the electromagnetic waves; a measurement part configured to measure, for each frequency, a power of the electromagnetic waves traveling from the electromagnetic wave generator to the resonating structure and a power of transmitted waves, reflected waves, or scattered waves of the electromagnetic waves in the resonating structure; and a controller, wherein prior to execution of the plasma processing, the controller performs: a measurement process for measuring the power of the electromagnetic waves and the power of the transmitted waves, the reflected waves, or the scattered waves with the measurement part, and a calculation process for calculating a resonance frequency of the resonating structure based on frequency distribution of characteristic values of the resonating structure, which are calculated from the power of the electromagnetic waves and the power of the transmitted waves, the reflected waves, or the scattered waves.

### BRIEF DESCRIPTION OF THE DRAWINGS

FIG. 1 is a schematic cross-sectional view showing an example of a configuration of a plasma processing apparatus according to a first embodiment.

FIG. 2 shows an example of a configuration of a microwave output device, a measurement device, and a tuner in the first embodiment.

FIG. 3 is a block diagram showing a specific example of a waveform generator.

FIG. 4 is a bottom plan view showing an example of a configuration of a dielectric window and a resonating structure according to the first embodiment.

FIG. 5 shows an example of a configuration of a first resonator according to the first embodiment.

FIG. 6 shows an example of a configuration of a second resonator according to the first embodiment.

FIG. 7 shows an example of a configuration of a third resonator according to the first embodiment.

FIG. 8 shows another example of the configuration of the third resonator according to the first embodiment.

FIG. 9 shows an example of dimensions of the resonator of the resonating structure used for examination.

FIG. 10 shows an example of the relationship between an outer diameter of a ring member and a theoretical value of a resonance frequency of the resonator included in the resonating structure.

FIG. 11 shows an example of the relationship between a thickness of a dielectric plate and a theoretical value of the resonance frequency of the resonator included in the resonating structure.

FIG. 12 shows an example of the relationship between a relative dielectric constant of a dielectric plate and a theoretical value of the resonance frequency of the resonator included in the resonating structure.

FIG. 13 shows an example of frequency distribution of a transmission characteristic value (S₂₁ value) of the resonating structure.

FIG. 14 explains deviation between a resonance frequency determined based on a design value and an actual resonance frequency in a processing chamber.

FIG. 15 is a flowchart showing a sequence of processing performed by a plasma processing apparatus according to the first embodiment.

FIG. 16 is a flowchart showing another example of a sequence of processing performed by the plasma processing apparatus according to the first embodiment.

FIG. 17 is a flowchart showing another example of a sequence of processing performed by the plasma processing apparatus according to the first embodiment.

FIG. 18 shows an example of a configuration of a microwave output device, a measurement device, and a tuner in a second embodiment.

FIG. 19 is a flowchart showing an example of a sequence of processing performed by a plasma processing apparatus according to the second embodiment.

FIG. 20 shows an example of a configuration of a microwave output device, a measurement device, and a tuner in a third embodiment.

FIG. 21 is a flowchart showing an example of a sequence of processing performed by a plasma processing apparatus according to the third embodiment.

### DETAILED DESCRIPTION

Hereinafter, embodiments of a plasma processing apparatus and a resonance frequency measuring method of the present disclosure will be described in detail with reference to the accompanying drawings. Further, the embodiments are not intended to limit the plasma processing apparatus and the resonance frequency measuring method of the present disclosure. Moreover, the embodiments can be appropriately combined without contradicting each other. Further, like reference numerals will be used for like or corresponding parts throughout the drawings.

In a plasma processing apparatus using microwaves for plasma excitation, the power of microwaves supplied into a processing chamber may be increased in order to increase the electron density of plasma. The electron density of the plasma can be increased by increasing the power of the microwaves supplied into the processing chamber.

Here, it is known that when the electron density of the plasma reaches a certain upper limit value by increasing the power of the microwaves supplied into the processing chamber, the dielectric constant of the space in the processing chamber becomes negative. The upper limit value of the electron density is appropriately referred to as “cutoff density.” Further, the refractive index is known as an index indicating whether or not microwaves propagate through a space. The refractive index N is expressed by the following Eq. (1).

$$N = √ ε √ μ \qquad Eq . ( 1 )$$

Here, & indicates a dielectric constant and u indicates magnetic permeability. The magnetic permeability is generally positive. Thus, when the dielectric constant of the space in the processing chamber becomes negative, the refractive index of the space in the processing chamber becomes a pure imaginary number according to the above Eq. (1). Accordingly, microwaves are attenuated and prevented from propagating through the space in the processing chamber. When the electron density of the plasma reaches the cutoff density, the microwaves cannot propagate in the space in the processing chamber, so that the power of the microwaves is not sufficiently absorbed by the plasma. As a result, it is difficult to increase the density of the plasma produced in the processing chamber over a wide range.

Thus, a technique in which a resonating structure formed by arranging a plurality of resonators capable of resonating with microwaves is provided in the processing chamber and the resonating structure and microwaves are resonated to increase a density of plasma using a negative refractive index is being examined. With this technique, due to the resonance between the resonating structure and the microwaves, the microwaves can be efficiently supplied to the space in the processing chamber and the magnetic permeability of the space in the processing chamber can become negative. When the magnetic permeability is negative, even if the electron density of the plasma produced in the space in the processing chamber reaches the cutoff density and the dielectric constant of the space in the processing chamber is negative, the refractive index becomes a negative real number according to the above Eq. (1), so that the microwaves can propagate in the space in the processing chamber. Accordingly, even if the electron density of the plasma reaches the cutoff density, the microwaves can propagate beyond the skin depth of the plasma and the power of the microwaves is efficiently absorbed by the plasma. As a result, high-density plasma can be generated over a wide range beyond the skin depth of the plasma.

The resonance between the resonating structure and the microwaves occurs when the frequency of the microwaves supplied to the processing chamber coincides with the resonance frequency of the resonating structure. Further, the resonance between the resonating structure and the microwaves is maintained even in a predetermined frequency band higher than the resonance frequency of the resonating structure. Therefore, in view of stably increasing a density of plasma by resonance, it is important to accurately measure the resonance frequency of the resonating structure.

However, the resonance frequency of the resonating structure varies due to the influence of the mechanical difference (e.g., dimensional errors, assembly errors, or the like) of the resonating structure, or the physical property (e.g., the dielectric constant of the dielectric material constituting the resonating structure) of the resonating structure. Further, the resonance frequency of the resonating structure varies depending on the environment in which the resonating structure is used (e.g., the temperature of the resonating structure). Therefore, even if the resonance frequency of the resonating structure is determined based on the design value, the determined resonance frequency may deviate from the actual resonance frequency of the resonating structure in the processing chamber. If the frequency of the microwaves supplied to the processing chamber deviates from the resonance frequency and a predetermined frequency band higher than the resonance frequency, the resonating structure and the microwaves do not resonate, so that the power of the microwaves is not sufficiently absorbed by the plasma, and an increase in a density of plasma is suppressed.

Therefore, in the present embodiment, the resonance frequency of the actual resonating structure disposed in the processing chamber is measured before the plasma processing is performed in the processing chamber. Accordingly, the resonance frequency of the resonating structure can be accurately measured without being affected by the mechanical difference of the resonating structure, which makes it possible to stably increase the density of the plasma by resonance.

### First Embodiment

### <Configuration of Plasma Processing Apparatus 1>

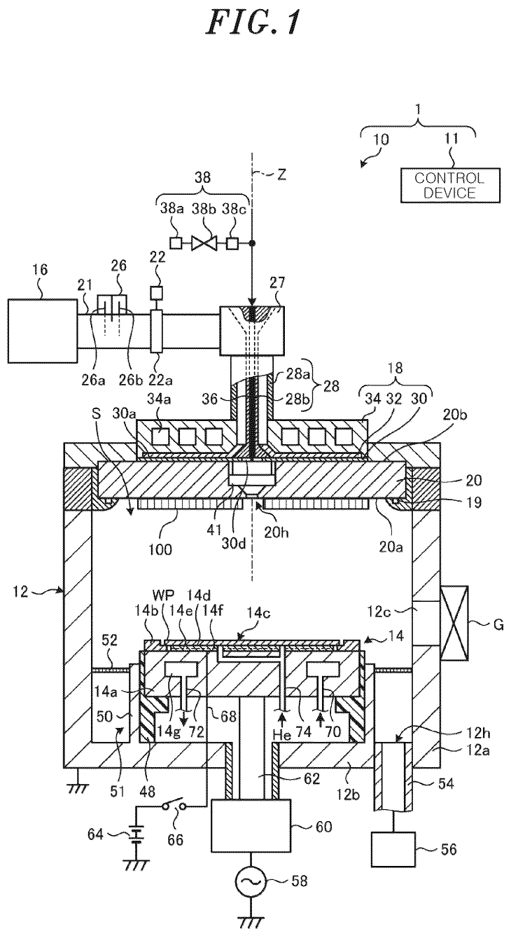

FIG. 1 is a schematic cross-sectional view showing an example of a configuration of a plasma processing apparatus 1 according to a first embodiment. The plasma processing apparatus 1 includes an apparatus main body 10 and a control device (an example of a controller) 11. The apparatus main body 10 includes a processing chamber 12, a stage 14, a microwave output device (an example of an electromagnetic wave generator) 16, an antenna 18, a dielectric window 20, and a resonating structure 100.

The processing chamber 12 is formed in a substantially cylindrical shape, and is made of, e.g., aluminum having an anodically oxidized surface. The processing chamber 12 provides a substantially cylindrical processing space S therein. The processing chamber 12 is frame grounded. Further, the processing chamber 12 has a sidewall 12a and a bottom portion 12b. The central axis of the sidewall 12a is defined as an axis Z. The bottom portion 12b is disposed on the lower end side of the sidewall 12a. An exhaust port 12h for exhaust is disposed at the bottom portion 12b. The upper end of the sidewall 12a is opened.

The sidewall 12a is provided with an opening 12c for loading/unloading a substrate WP to be processed. The opening 12c is opened/closed by a gate valve G.

A dielectric window 20 is disposed at the upper end of the sidewall 12a, and closes the opening at the upper end of the sidewall 12a from the top. The bottom surface (an example of a first surface) 20a of the dielectric window (an example of a dielectric) 20 faces the processing space S. In other words, the dielectric window 20 is installed with the bottom surface 20a facing the processing space S. An O-ring 19 is disposed between the dielectric window 20 and the upper end of the sidewall 12a.

The stage 14 is accommodated in the processing chamber 12. The stage 14 is disposed to face the dielectric window 20 in the direction of the axis Z. The space between the stage 14 and the dielectric window 20 serves as the processing space S. The substrate WP is placed on the stage 14.

The stage 14 has a base 14a and an electrostatic chuck 14c. The base 14a is formed in a substantially disc shape, and is made of a conductive material such as aluminum or the like. The base 14a is disposed in the processing chamber 12 such that the central axis of the base 14a substantially coincides with the axis Z.

The base 14a is supported by a cylindrical support 48 made of an insulating material and extending in the direction of the Z-axis. A conductive cylindrical support 50 is disposed at the outer periphery of the cylindrical support 48. The cylindrical support 50 extends from the bottom portion 12b of the processing chamber 12 toward the dielectric window 20 along the outer periphery of the cylindrical support 48. An annular exhaust line 51 is formed between the cylindrical support 50 and the sidewall 12a.

An annular baffle plate 52 having a plurality of through-holes formed in a thickness direction is disposed at the upper part of the exhaust line 51. The above-described exhaust port 12h is disposed below the baffle plate 52. An exhaust device 56 having a vacuum pump such as a turbo molecular pump or an automatic pressure control valve is connected to the exhaust port 12h via an exhaust line 54. The exhaust device 56 can reduce a pressure in the processing space S to a desired vacuum level.

The base 14a functions as a high-frequency electrode. A high-frequency power supply 58 for RF bias is electrically connected to the base 14a via a power supply rod 62 and a matching unit 60. The high-frequency power supply 58 supplies a bias power of a predetermined frequency (e.g., 13.56 MHz) suitable for controlling the energy of ions attracted to the substrate WP to the base 14a via the matching unit 60 and the power supply rod 62.

The matching unit 60 includes a matching device for matching the impedance of the high-frequency power supply 58 side with the impedance of the load side, mainly the electrode, the plasma, and the processing chamber 12. A blocking capacitor for generating a self-bias is included in the matching device.

The electrostatic chuck 14c is disposed on the upper surface of the base 14a. The electrostatic chuck 14c is disposed on the upper surface of the base 14a such that the central axis of the electrostatic chuck 14c substantially coincides with the axis Z. The electrostatic chuck 14c attracts and holds the substrate WP by an electrostatic force. The electrostatic chuck 14c has a substantially disc-shaped outer shape, and includes an electrode 14d, an insulating film (dielectric film) 14e, and an insulating film (dielectric film) 14f. The electrode 14d of the electrostatic chuck 14c is made of a conductive film, and is disposed between the insulating film 14e and the insulating film 14f. The electrode 14d is electrically connected to a DC power supply 64 via a coated wire 68 and a switch 66. The electrostatic chuck 14c can attract and hold the substrate WP on the upper surface thereof by an electrostatic force generated by a DC voltage applied from the DC power supply 64. Further, an edge ring 14b is disposed on the base 14a. The edge ring 14b is disposed to surround the substrate WP and the electrostatic chuck 14c. The edge ring 14b is also referred to as “focus ring.”

A channel 14g is disposed in the base 14a. A coolant is supplied to the channel 14g from a chiller unit (not shown) via a line 70. The coolant supplied to the channel 14g is returned to the chiller unit via a line 72. The temperature of the base 14a is controlled by circulating the coolant of which temperature is controlled by the chiller unit in the channel 14g of the base 14a. By controlling the temperature of the base 14a, the temperature of the substrate WP on the electrostatic chuck 14c is controlled via the electrostatic chuck 14c on the base 14a.

Further, a line 74 for supplying a heat transfer gas, such as He gas, to the gap between the upper surface of the electrostatic chuck 14c and the backside of the substrate WP is formed in the stage 14.

The microwave output device 16 outputs microwaves (an example of electromagnetic waves) for exciting the processing gas supplied to the processing chamber 12. The microwave output device 16 can adjust the frequency, the power, and the bandwidth of the microwaves. The microwave output device 16 can generate microwaves (hereinafter, appropriately referred to as “single peak (SP) microwaves”) including a single frequency component by setting the bandwidth of the microwaves to about 0, for example. Moreover, the microwave output device 16 can generate microwaves (hereinafter, appropriately referred to as “broadband (BB) microwaves”) including a plurality of frequency components belonging to a predetermined frequency bandwidth. The power of the plurality of frequency components may be the same, or only the central frequency component in the band may have a power greater than the power of the other frequency components. The microwave output device 16 can adjust the power of the microwaves within a range of 0 W to 5000 W, for example. The microwave output device 16 can adjust the frequency of the microwaves or the central frequency of the BB microwaves within a range of 2.3 GHZ to 2.5 GHZ, for example, and can adjust the bandwidth of the BB microwaves within a range of 0 MHz to 100 MHZ, for example. Further, the microwave output device 16 can adjust the frequency pitch (carrier pitch) of the plurality of frequency components of the BB microwaves within a range of 0 KHz to 25 kHz, for example.

Further, the apparatus main body 10 includes a waveguide 21, a measurement device (an example of a measurement part) 22, a tuner 26, a mode converter 27, and a coaxial waveguide 28. The output part of the microwave output device 16 is connected to one end of the waveguide 21. The other end of the waveguide 21 is connected to the mode converter 27. The waveguide 21 is a rectangular waveguide, for example.

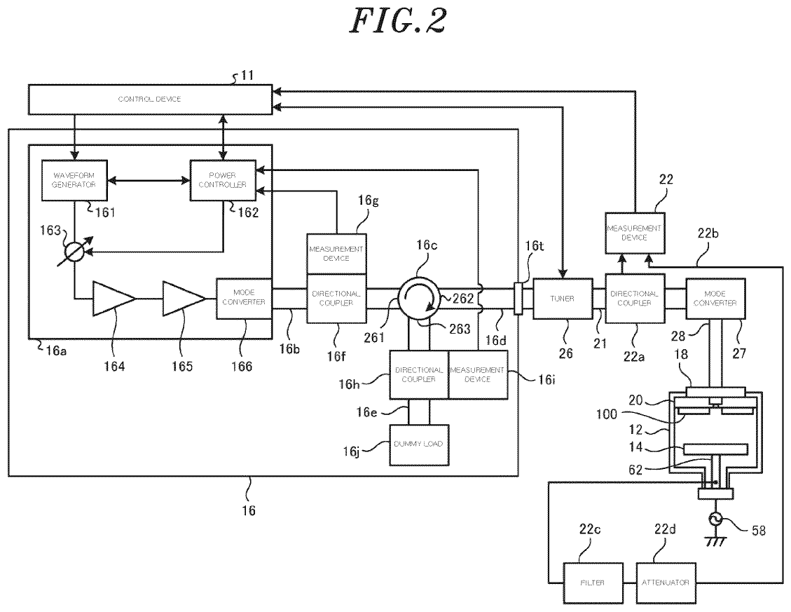

The measurement device 22 is connected to the waveguide 21 via a directional coupler 22a disposed in the waveguide 21. The directional coupler 22a branches a part of the microwaves (i.e., the traveling waves) traveling from the microwave output device 16 toward the processing chamber 12, and outputs a part of the traveling waves to the measurement device 22. The measurement device 22 measures, for each frequency, the power of the traveling waves propagating through the waveguide 21 based on the part of the traveling waves outputted from the directional coupler 22a, and outputs the measurement result to the control device 11. Further, the measurement device 22 measures, for each frequency, the power of the microwaves (i.e., transmitted waves) that have transmitted through the resonating structure 100 and returned from the processing chamber 12 side through a waveguide 22b (see FIG. 2) to be described later, and outputs the measurement results to the control device 11.

The tuner 26 is disposed in the waveguide 21. The tuner 26 has movable plates 26a and 26b. By adjusting the protruding amounts of the movable plates 26a and 26b with respect to the inner space of the waveguide 21, the impedance of the microwave output device 16 and the impedance of the load can be matched.

The mode converter 27 converts the mode of the microwaves outputted from the waveguide 21, and supplies the microwaves after the mode conversion to the coaxial waveguide 28. The coaxial waveguide 28 includes an outer conductor 28a and an inner conductor 28b. The outer conductor 28a and the inner conductor 28b have a substantially cylindrical shape. The outer conductor 28a and the inner conductor 28b are disposed above the antenna 18 such that the central axes of the outer conductor 28a and the inner conductor 28b substantially coincide with the axis Z. The coaxial waveguide 28 transmits the microwaves of which mode has been converted by the mode converter 27 to the antenna 18.

The antenna 18 supplies microwaves into the processing chamber 12. The antenna 18 is an example of an electromagnetic wave supply part. The antenna 18 is disposed on the upper surface 20b of the dielectric window 20, and supplies microwaves to the processing space S through the dielectric window 20. The antenna 18 includes a slot plate 30, a dielectric plate 32, and a cooling jacket 34. The slot plate 30 is formed in a substantially circular plate shape, and is made of a conductive metal. The slot plate 30 is disposed on the upper surface 20b of the dielectric window 20 such that the central axis of the slot plate 30 coincides with the axis Z. A plurality of slot holes 30a are formed in the slot plate 30. The plurality of slot holes 30a form a plurality of slot pairs, for example. Each of the plurality of slot pairs includes two slot holes 30a formed in the shape of long holes extending in directions intersecting each other. The plurality of slot pairs are arranged along one or more concentric circles around the central axis of the slot plate 30. Further, a through-hole 30d through which a conduit 36 to be described later can pass is formed at the center of the slot plate 30.

The dielectric plate 32 is formed in a substantially disc shape, and is made of a dielectric material such as quartz or the like. The dielectric plate 32 is disposed on the slot plate 30 such that the central axis of the dielectric plate 32 substantially coincides with the axis Z. The cooling jacket 34 is disposed on the dielectric plate 32. The dielectric plate 32 is disposed between the cooling jacket 34 and the slot plate 30.

The cooling jacket 34 has a conductive surface. A channel 34a is formed in the cooling jacket 34. A coolant is supplied to the channel 34a from a chiller unit (not shown). The lower end of the outer conductor 28a is electrically connected to the upper surface of the cooling jacket 34. The lower end of the inner conductor 28b is electrically connected to the slot plate 30 through an opening formed in the center of the cooling jacket 34 and the dielectric plate 32.

The microwaves propagating through the coaxial waveguide 28 propagate through the dielectric plate 32, and then are radiated into the processing space S through the dielectric window 20 from the plurality of slot holes 30a of the slot plate 30.

The conduit 36 is formed in the inner conductor 28b of the coaxial waveguide 28. A through-hole 30d through which the conduit 36 can pass is formed in the center of the slot plate 30. The conduit 36 extends through the inside of the inner conductor 28b, and is connected to a gas supply part 38.

The gas supply part 38 supplies a processing gas for processing the substrate WP to the conduit 36. The gas supply part 38 includes a gas supply source 38a, a valve 38b, and a flow rate controller 38c. The gas supply source 38a is a supply source of the processing gas. The valve 38b controls supply and supply stop of the processing gas from the gas supply source 38a. The flow rate controller 38c is a mass flow controller, for example, and controls the flow rate of the processing gas supplied from the gas supply source 38a to the conduit 36.

An injector 41 is disposed at the dielectric window 20. The injector 41 supplies a gas from the conduit 36 to the through-hole 20h formed in the dielectric window 20. The gas supplied to the through-hole 20h of the dielectric window 20 is injected into the processing space S and excited by the microwaves radiated from the dielectric window 20 into the processing space S. As a result, the processing gas is turned into plasma in the processing space S, and the substrate WP on the electrostatic chuck 14c is processed by ions and radicals contained in the plasma.

The resonating structure 100 is disposed in the processing chamber 12, and is formed by arranging a plurality of resonators. The resonators are capable of resonating with the magnetic field component of the microwaves and have sizes smaller than the wavelength of the microwaves.

Since the resonating structure 100 is disposed in the processing chamber 12, the microwaves supplied to the processing space S by the antenna 18 can resonate with the resonating structure 100. Due to the resonance between the microwaves and the resonating structure 100, the microwaves can be efficiently supplied to the processing space S of the processing chamber 12 and the magnetic permeability of the processing space S can become negative. When the magnetic permeability of the processing space S is negative, even if the electron density of the plasma produced in the processing space S reaches the cutoff density and the dielectric constant of the processing space S is negative, the refractive index becomes a real number according to the above Eq. (1), so that the microwaves can propagate in the processing space S. Accordingly, even if the electron density of the plasma produced in the processing space S reaches the cutoff density, the microwaves can propagate beyond the skin depth of the plasma, and the microwave power can be efficiently absorbed by the plasma. As a result, high-density plasma can be generated over a wide range beyond the skin depth of the plasma. In other words, in accordance with the plasma processing apparatus 1 of the present embodiment, the resonating structure 100 is disposed in the processing chamber 12, so that the density of the plasma can be increased over a wide range. The specific configuration of the resonating structure 100 will be described later.

The control device 11 has a processor, a memory, and an input/output interface. The memory stores programs, process recipes, and the like. The processor reads and executes the program from the memory, thereby controlling individual components of the apparatus main body 10 via the input/output interface based on the process recipe stored in the memory.

### <Specific Description of Microwave Output Device 16, Measurement Device 22, and Tuner 26>

FIG. 2 shows an example of the configuration of the microwave output device 16, the measurement device 22, and the tuner 26 in the first embodiment. The microwave output device 16 includes a microwave generator 16a, a waveguide 16b, a circulator 16c, a waveguide 16d, a waveguide 16e, a directional coupler 16f, a measurement device 16g, a directional coupler 16h, a measurement device 16i, and a dummy load 16j. The microwave generator 16a includes a waveform generator 161, a power controller 162, an attenuator 163, an amplifier 164, an amplifier 165, and a mode converter 166.

The waveform generator 161 generates the SP microwaves or the BB microwaves in a predetermined frequency range (e.g., 2.4 GHz to 2.5 GHZ). The SP microwaves have a single peak (frequency component) at a specified frequency. The BB microwaves have a specified bandwidth at a specified center frequency. Further, the waveform generator 161 can sweep the frequency of the single frequency component of the SP microwaves from a specified frequency to a specified frequency at a specified sweep speed.

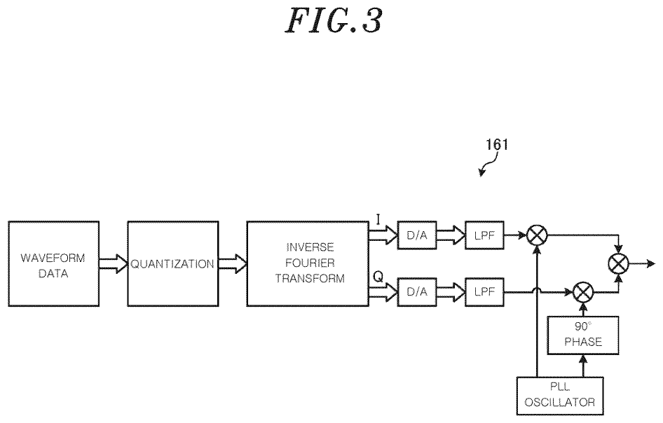

FIG. 3 is a block diagram showing a specific example of the waveform generator 161. The waveform generator 161 has a phase locked loop (PLL) oscillator that outputs microwaves, and an IQ digital modulator connected to the PLL oscillator, for example. The waveform generator 161 sets the frequency of the microwaves outputted from the PLL oscillator to a frequency within a set frequency range specified by the control device 11. Further, the waveform generator 161 modulates the microwaves outputted from the PLL oscillator and microwaves having a phase difference of 90° from the microwaves outputted from the PLL oscillator using the IQ digital modulator. Accordingly, the waveform generator 161 generates microwaves with a frequency within the set frequency range.

The waveform generator 161 can generate frequency-modulated microwaves by sequentially inputting N pieces of waveform data from a start frequency to an end frequency, for example, according to a scanning speed, and performing quantization and inverse Fourier transform.

In the present embodiment, the waveform generator 161 has waveform data represented by a sequence of pre-digitized codes. The waveform generator 161 quantizes the waveform data and applies inverse Fourier transform to the quantized data to generate I data and Q data. Then, the waveform generator 161 converts the I data and the Q data, which are digital signals, into analog signals. Then, the waveform generator 161 extracts low-frequency components from each of the converted analog signals using a low pass filter (LPF). Then, the waveform generator 161 mixes the I component analog signal with the microwaves outputted from the PLL, and mixes the Q component analog signal with the microwaves having a phase difference of 90° from the microwaves outputted from the PLL. Then, the waveform generator 161 generates frequency-modulated microwaves by synthesizing the two mixed analog signals.

The method of generating microwaves by the waveform generator 161 is not limited to the method illustrated in FIG. 3, and microwaves may be generated using a direct digital synthesizer (DDS) and a voltage controlled oscillator (VCO).

Referring back to FIG. 2, the description continues. The microwaves outputted from the waveform generator 161 are inputted to the attenuator 163. A power controller 162 is connected to the attenuator 163. The power controller 162 may be a processor, for example. The power controller 162 controls the attenuation rate in the attenuator 163 such that microwaves having a power specified by the control device 11 are outputted from the microwave output device 16. The microwaves outputted from the attenuator 163 are outputted to the mode converter 166 via the amplifiers 164 and 165. The amplifiers 164 and 165 amplify the microwaves at a set amplification factor. The mode converter 166 converts the mode of the microwaves amplified by the amplifier 165.

The output end of the microwave generator 16a is connected to one end of the waveguide 16b. The other end of the waveguide 16b is connected to a first port 261 of the circulator 16c. The directional coupler 16f is disposed in the waveguide 16b. Further, the directional coupler 16f may be disposed in the waveguide 16d. The directional coupler 16f branches a part of the microwaves (i.e., traveling waves) outputted from the microwave generator 16a and propagating to the circulator 16c, and outputs a part of the traveling waves to the measurement device 16g. The measurement device 16g measures the power of the traveling waves propagating through the waveguide 16d based on the part of the traveling waves outputted from the directional coupler 16f, and outputs the measurement result to the power controller 162.

The circulator 16c has a first port 261, a second port 262, and a third port 263. The circulator 16c outputs the microwaves inputted to the first port 261 from the second port 262, and outputs the microwaves inputted to the second port 262 from the third port 263. One end of the waveguide 16d is connected to the second port 262 of the circulator 16c. The other end of the waveguide 16d is provided with an output end 16t of the microwave output device 16.

One end of the waveguide 16e is connected to the third port 263 of the circulator 16c, and the other end of the waveguide 16e is connected to the dummy load 16j. The directional coupler 16h is disposed in the waveguide 16e. Further, the directional coupler 16h may be disposed in the waveguide 16d. The directional coupler 16h branches a part of the microwaves (i.e., reflected waves) propagating through the waveguide 16e, and outputs a part of the reflected waves to the measurement device 16i. The measurement device 16i measures the power of the reflected waves propagating through the waveguide 16d based on a part of the reflected waves outputted from the directional coupler 16h, and outputs the measurement result to the power controller 162.

The dummy load 16j receives the microwaves propagating through the waveguide 16e and absorbs the microwaves. The dummy load 16j converts the microwaves into heat, for example.

The power controller 162 controls the waveform generating device 161 and the attenuator 163 such that the difference between the power of the traveling waves measured by the measurement device 16g and the power of the reflected waves measured by the measurement device 16i becomes the power specified by the control device 11. The difference between the power of the traveling waves measured by the measurement device 16g and the power of the reflected waves measured by the measurement device 16i is the power supplied to the processing chamber 12.

The tuner 26 is disposed in the waveguide 21, and adjusts the protruding position of the movable plate based on a control signal from the control device 11 to match the impedance on the microwave output device 16 side with the impedance on the processing chamber 12 side. The tuner 26 operates the movable plate by a driver circuit and an actuator (both not shown). The protruding position of the movable plate may be adjusted by a stub structure.

The measurement device 22 is connected to the waveguide 21 via the directional coupler 22a disposed in the waveguide 21. The directional coupler 22a branches a part of the microwaves (i.e., the traveling waves) traveling from the microwave output device 16 to the processing chamber 12 side, and outputs a part of the traveling waves to the measurement device 22. The measurement device 22 measures, for each frequency, the power of the traveling waves propagating through the waveguide 21 based on the part of the traveling waves outputted from the directional coupler 22a, and outputs the measurement result to the control device 11.

Further, the measurement device 22 is connected to the power supply rod 62 in the processing chamber 12 via the waveguide 22b. The waveguide 22b branches a part of the microwaves (i.e., the transmitted waves) that have transmitted through the resonating structure 100 and propagated to the stage 14 and the power supply rod 62, and returns the part of the transmitted waves from the processing chamber 12 side to the measurement device 22. The measurement device 22 measures, for each frequency, the power of the transmitted waves that have transmitted through the resonating structure 100 based on the part of the transmitted waves returned from the waveguide 22b, and outputs the measurement result to the control device 11.

A filter 22c and an attenuator 22d are disposed in the waveguide 22b. The filter 22c removes noise components from the microwaves propagating through the waveguide 22b. The attenuator 22d attenuates the microwaves propagating through the waveguide 22b at a set attenuation rate.

### <Specific Description of Resonating Structure 100>

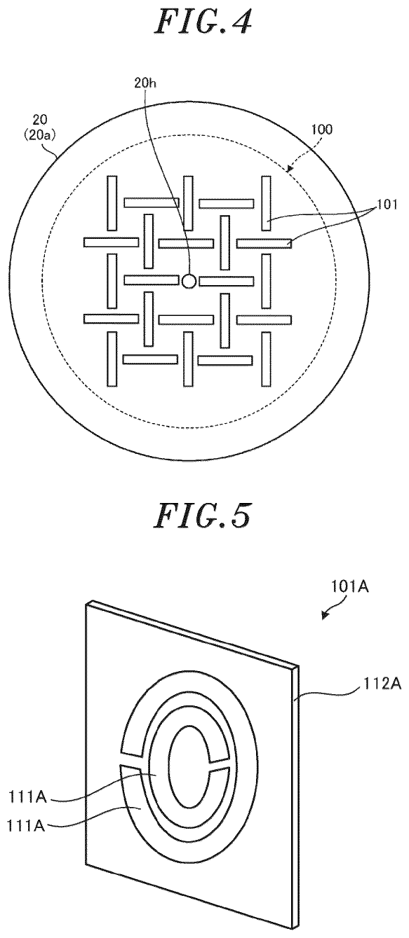

The specific configuration of the resonating structure 100 will be described with reference to FIGS. 1 and 4. FIG. 4 is a bottom plan view showing an example of the configuration of the dielectric window 20 and the resonating structure 100 according to the first embodiment. In FIG. 4, the bottom surface 20a of the dielectric window 20 is illustrated in a disc shape.

As shown in FIGS. 1 and 4, the resonating structure 100 is disposed along the bottom surface 20a of the dielectric window 20.

The resonating structure 100 is formed by arranging a plurality of resonators 101 in a lattice shape, each of which is capable of resonating with the magnetic field component of microwaves and has a size smaller than the wavelength of the microwaves. Specifically, the plurality of resonators 101 includes at least one of the first resonator 101A, the second resonator 101B, or the third resonator 101C shown in FIGS. 5 to 7. Each of the plurality of resonators 101 constitutes a series resonant circuit including a capacitor equivalent element and a coil equivalent element. The series resonant circuit is realized by patterning a conductor on the plane.

FIG. 5 shows an example of the configuration of the first resonator 101A according to the first embodiment. The first resonator 101A shown in FIG. 5 has a structure in which two C-shaped ring members 111A made of a conductor and arranged in a concentric shape in opposite directions are stacked on one surface of a dielectric plate 112A. Capacitor equivalent elements are formed on the opposing surfaces of the inner ring member 111A and the outer ring member 111A, or at both ends of each ring member 111A. Coil equivalent elements are formed along the ring members 111A. Accordingly, the first resonator 101A can constitute a series resonant circuit.

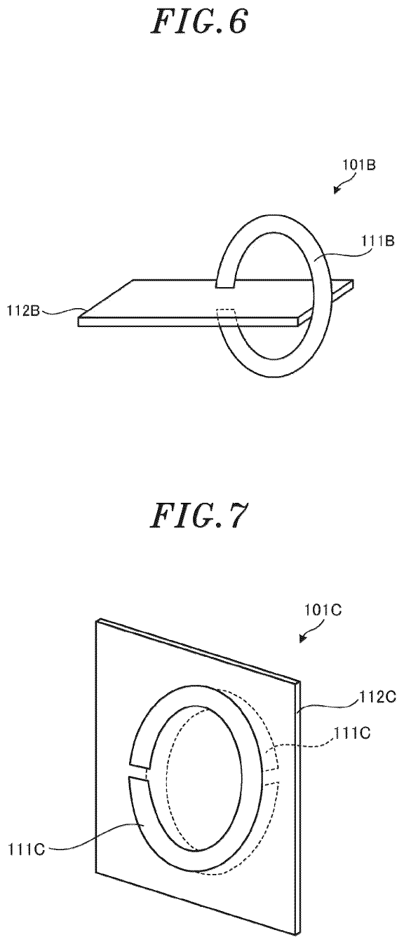

FIG. 6 shows an example of the configuration of a second resonator 101B according to the first embodiment. The second resonator 101B shown in FIG. 6 has a structure in which a dielectric plate 112B is embedded between both ends of a C-shaped ring member 111B made of a conductor. Capacitor equivalent elements are formed at both ends of the ring member 111B, and a coil equivalent element is formed along the ring member 111B. Accordingly, the second resonator 101B can constitute a series resonant circuit. Further, in the second resonator 101B shown in FIG. 6, another dielectric plate different from the dielectric plate 112B may be bonded to one surface of the ring member 111B.

FIG. 7 shows an example of the configuration of the third resonator 101C according to the first embodiment. The third resonator 101C shown in FIG. 7 has a structure in which a dielectric plate 112C is disposed between two C-shaped ring members 111C made of a conductor and arranged adjacent to each other in opposite directions. In other words, in the third resonator 101C, the dielectric plate 112C is embedded between the two C-shaped ring members 111C arranged in opposite directions. Capacitor equivalent elements are formed on the opposing surfaces of the two C-shaped ring members 111C, or at both ends of each ring member 111C. Coil equivalent elements are formed along the ring members 111C. Accordingly, the third resonator 101C can constitute a series resonant circuit.

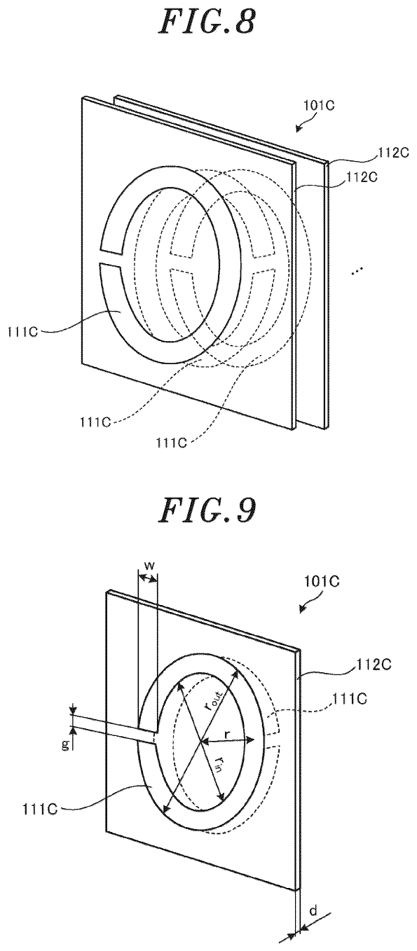

In the third resonator 101C shown in FIG. 7, the number of arrangement (hereinafter, also referred to as “number of layers”) of the ring members 111C is two, but the number of layers of the ring members 111C may be greater than two. FIG. 8 shows another example of the configuration of the third resonator 101C according to the first embodiment. The third resonator 101C shown in FIG. 8 has a structure in which a dielectric plate 112C is disposed between n (n=2) number of C-shaped ring members 111C made of a conductor and arranged adjacent to each other in the opposite directions. Also with this structure, the third resonator 101C can constitute a series resonant circuit.

<Change in resonance frequency of resonator included in resonating structure 100>

Next, the change in the resonance frequency of the resonating structure 100 will be described with reference to FIGS. 9 to 12. As described above, the resonance frequency of the resonating structure 100 changes due to the influence of the mechanical difference (e.g., dimensional errors, assembly errors, and the like) of the resonating structure 100, or the physical property (e.g., the dielectric constant of the dielectric material constituting the resonating structure 100) of the resonance structure 100. This is considered to be because the resonance frequency of the resonator included in the resonating structure 100 changes due to the influence of the mechanical difference or the physical property of the resonator. The inventors of the present disclosure have examined the change in the theoretical value of the resonance frequency using a theoretical equation in the case of changing the mechanical difference and the physical property of the resonator included in the resonating structure 100.

FIG. 9 shows an example of dimensions of the resonator of the resonating structure 100 used for examination. The resonator used for examination is the third resonator 101C shown in FIG. 7. The dimensions and physical properties of the third resonator 101C are defined as follows:
w: width of the ring member 111C
g: distance between both ends of the ring member 111C
r: radius of the ring member 111C
rₒᵤₜ: outer diameter of the ring member 111C
rᵢₙ: inner diameter of the ring member 111C
d: thickness of the dielectric plate 112C
ε: relative dielectric constant of the dielectric plate 112C

The theoretical value fro of the resonance frequency of the third resonator 101C is expressed by the following Eq. (2).

$${f}_{r 0} = 1 / ( 2 π √ LC ) \qquad Eq . ( 2 )$$

Here, L indicates the inductance of the third resonator 101C, and C indicates the capacitance of the third resonator 101C.

Further, the inductance L of the third resonator 101C is expressed by the following Eq. (3).

$$L = {μ}_{0 r} ( log ( 4 π ) - 1 ) \qquad Eq . ( 3 )$$

Here, μ0 indicates the magnetic permeability of vacuum.

Further, the capacitance C of the third resonator 101C is expressed by the following Eqs. (4) and (5).

$$C = 1 / ( 1 / {C}_{half} + 1 / {C}_{half} ) \qquad Eq . ( 4 )$$

$${C}_{half} = ε {ε}_{0} ( π ( {r}_{out}^{2} - {r}_{in}^{2} ) - gw ) / ( 2 d ) \qquad Eq . ( 5 )$$

Here, ε₀ indicates the dielectric constant of vacuum.

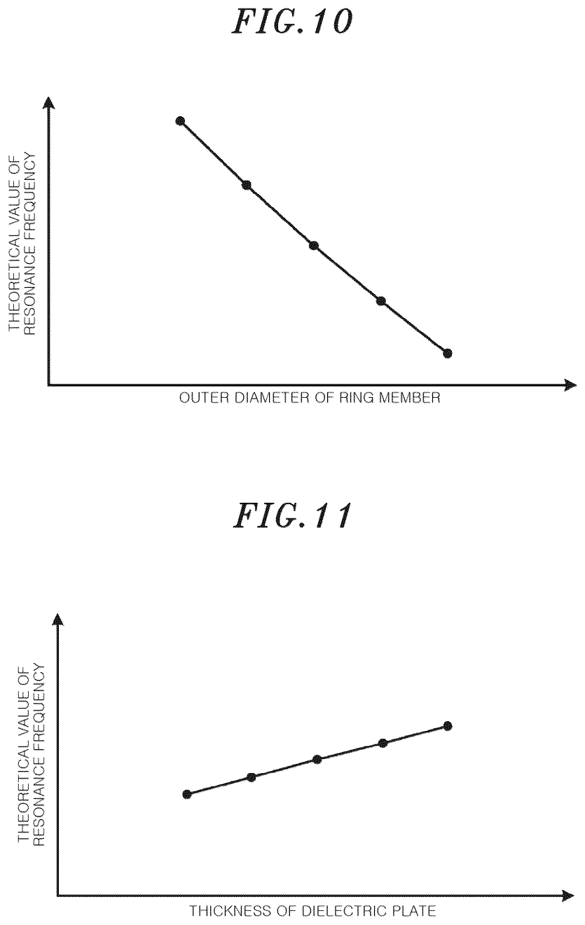

FIG. 10 shows an example of the relationship between the outer diameter of the ring member 111C and the theoretical value of the resonance frequency of the resonator included in the resonating structure 100. As shown in FIG. 10, the resonance frequency of the resonator included in the resonating structure 100 changes depending on the change in the outer diameter of the ring member 111C.

FIG. 11 shows an example of the relationship between the thickness of the dielectric plate 112C and the theoretical value of the resonance frequency of the resonator included in the resonating structure 100. As shown in FIG. 11, the resonance frequency of the resonator included in the resonating structure 100 changes depending on the change in the thickness of the dielectric plate 112C.

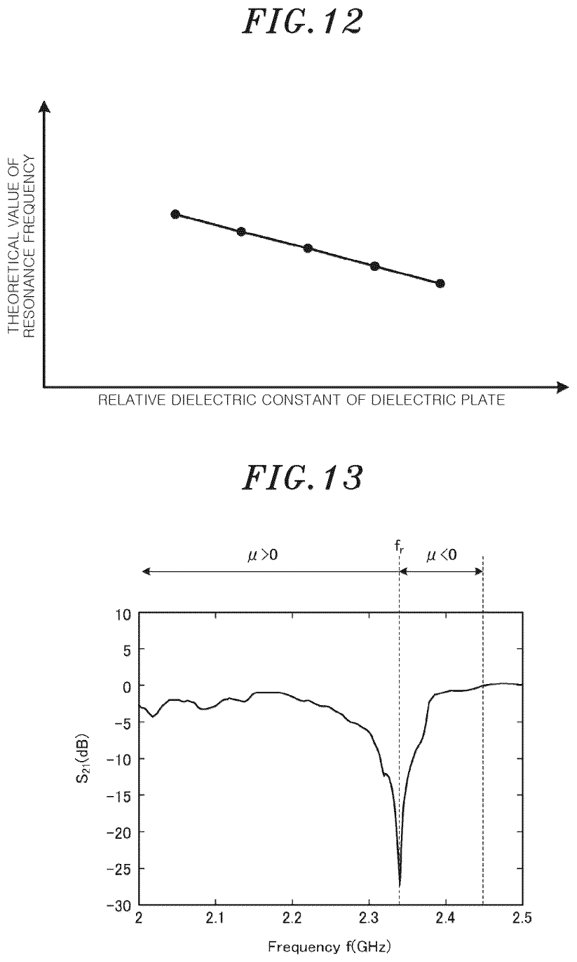

FIG. 12 shows an example of the relationship between the relative dielectric constant of the dielectric plate 112C and the theoretical value of the resonance frequency of the resonator included in the resonating structure 100. As shown in FIG. 12, the resonance frequency of the resonator included in the resonating structure 100 changes depending on the change in the relative dielectric constant of the dielectric plate 112C.

From the examination results of FIGS. 10 to 12, it was confirmed that the resonance frequency of the resonator included in the resonating structure 100 changes due to the influence of the mechanical difference or the physical property of the resonator. In other words, it was confirmed that the resonance frequency of the resonating structure 100 changes due to the influence of the mechanical difference or the physical property of the resonating structure 100.

### <Frequency Distribution of Transmission Characteristic Value of Resonating Structure 100>

FIG. 13 shows an example of the frequency distribution of the transmission characteristic value (S₂₁ value) of the resonating structure 100. FIG. 13 plots, for each frequency of the SP microwaves, the S₂₁ value of the resonating structure 100 in the case of supplying the SP microwaves to the processing space S in the processing chamber 12. The S₂1 value of the resonating structure 100 is calculated by log (P2/P1), where P1 is the power of the traveling waves and P2 is the power of the transmitted waves.

In the example of FIG. 13, when the frequency of the microwaves supplied to the processing space S coincides with the resonance frequency fᵣ (=approximately 2.35 GHZ) of the resonating structure 100, the S₂₁ value of the resonating structure 100 becomes a minimum value, and the resonance between the microwaves and the resonating structure 100 occurs. The resonance between the microwaves and the resonating structure 100 is maintained even in a predetermined frequency band (e.g., in a range of about 0.1 GHz from the resonance frequency fᵣ) higher than the resonance frequency fᵣ of the resonating structure 100. In a predetermined frequency band higher than the resonance frequency fᵣ of the resonating structure 100, both the dielectric constant and the magnetic permeability of the processing space S can become negative by the resonance between the microwaves and the resonating structure 100, and the microwaves can propagate in the processing space S as can be seen from the above Eq. (1).

Therefore, if the microwaves including frequency components in a target frequency band (e.g., in a range of about 0.1 GHZ) higher than the resonance frequency fᵣ of the resonating structure 100 are supplied to the processing space S in the processing chamber 12, the microwaves and the resonating structure 100 can resonate. Then, due to the resonance between the microwaves and the resonating structure 100, both the dielectric constant and the magnetic permittivity of the processing space S can become negative. Therefore, even if the electron density of the plasma reaches the cutoff density, the microwaves can propagate beyond the skin depth of the plasma, and the power of the microwaves can be efficiently absorbed by the plasma. As a result, the density of the plasma can be stably increased by resonance.

However, the resonance frequency fᵣ of the resonating structure 100 changes due to the influence of the mechanical difference (e.g., dimensional errors, assembly errors, and the like) of the resonating structure 100 and the physical property (e.g., the dielectric constant of the dielectric material constituting the resonating structure 100, or the like) of the resonating structure 100. Accordingly, the resonance frequency of the resonating structure 100 may be different in different plasma processing apparatuses 1. Further, even in the same plasma processing apparatus 1, thermal expansion and contraction of each resonator in the resonating structure 100 occurs due to the influence of the environment (e.g., the temperature of the resonating structure 100) in which the resonating structure 100 is used, and the resonance frequency fᵣ of the resonating structure 100 changes. Therefore, even if the resonance frequency fᵣ of the resonating structure 100 is determined based on the design value, the determined resonance frequency fᵣ may be different from the actual resonance frequency fᵣ of the resonating structure 100 in the processing chamber.

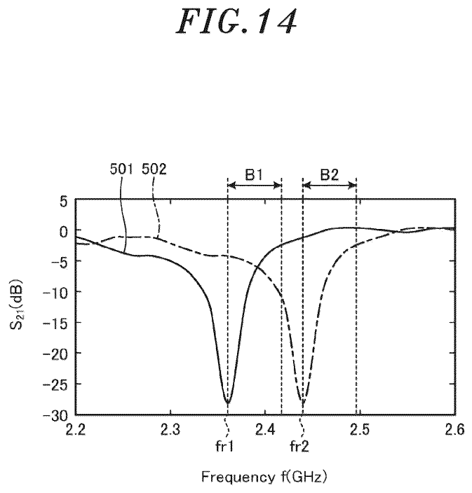

FIG. 14 explains deviation between the resonance frequency fᵣ₁ determined based on the design value and the actual resonance frequency fᵣ₂ in the processing chamber 12. Graph 501 in FIG. 14 is a graph showing the frequency distribution of the transmission characteristic value (S₂₁ value) of the resonating structure 100 including the resonance frequency fᵣ₁ determined based on the design value. Graph 502 in FIG. 14 is a graph showing the frequency distribution of the transmission characteristic value (S₂₁ value) including the actual resonance frequency fᵣ₂ in the processing chamber 12. As shown in FIG. 14, the actual resonance frequency fᵣ₂ in the processing chamber 12 deviates from the resonance frequency fᵣ determined based on the design value depending on the mechanical difference and the physical property of the resonating structure 100, and the environment where the resonating structure 100 is used. Further, due to the deviation between the resonance frequency fᵣ₁ and the resonance frequency fᵣ₂, a target frequency band B1 corresponding to the resonance frequency fᵣ₁ and a target frequency band B2 corresponding to the resonance frequency fᵣ₂ deviate from each other. If the microwave frequency deviates from the target frequency band due to the change in the target frequency band, the microwaves and the resonating structure 100 do not resonate. Therefore, the microwave power is not sufficiently absorbed by the plasma, and the increase in the density of the plasma is hindered.

On the other hand, in the plasma processing apparatus 1 of the present embodiment, the resonance frequency of the actual resonating structure 100 provided in the processing chamber 12 is measured before the plasma processing is performed in the processing chamber 12. Accordingly, in the plasma processing apparatus 1, the resonance frequency of the resonating structure 100 can be accurately measured without being affected by the mechanical difference of the resonating structure 100, which makes it possible to accurately determine the target frequency band corresponding to the resonance frequency. As a result, in the plasma processing apparatus 1, it is possible to prevent the frequency of the microwaves supplied to the processing space S in the processing chamber 12 from deviating from the target frequency band. Hence, during the plasma processing, the dielectric constant and the magnetic permeability of the processing space S can be maintained at a negative level due to the resonance between the microwaves and the resonating structure 100, thereby stably increasing the density of the plasma.

### <Specific Operation of Plasma Processing Apparatus 1>

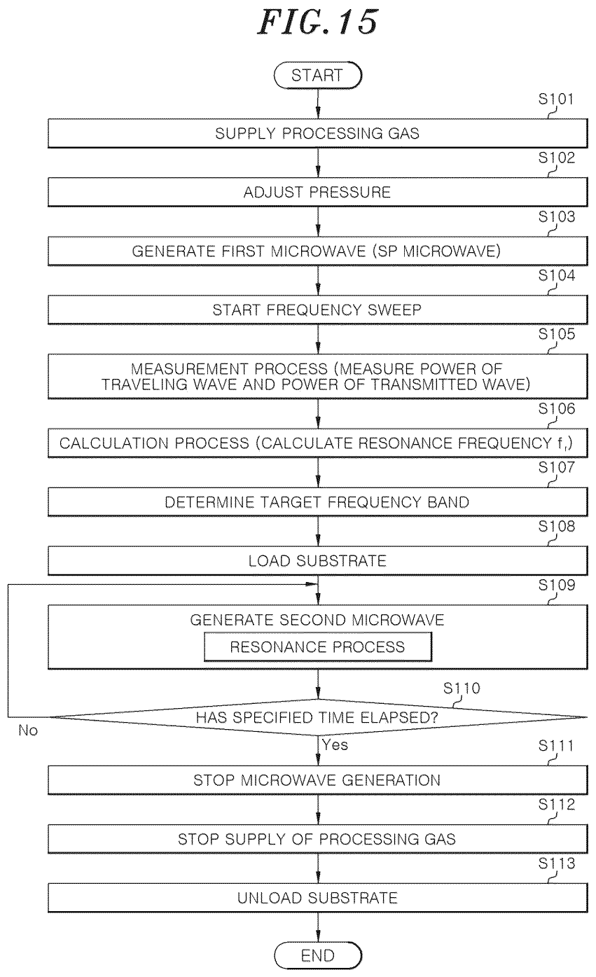

Next, a specific operation of the plasma processing apparatus 1 according to the first embodiment will be described with reference to FIG. 15. FIG. 15 is a flowchart showing a sequence of processing performed by the plasma processing apparatus 1 according to the first embodiment. Further, each step shown in FIG. 15 is realized by controlling individual components of the apparatus main body 10 with the control device 11.

First, the control device 11 opens the valve 38b and controls the flow controller 38c to supply the processing gas of a predetermined flow rate into the processing chamber 12, thereby starting the gas supply to the processing space S in the processing chamber 12 (step S101). Then, the control device 11 controls the exhaust device 56 to adjust the pressure in the processing chamber 12 (step S102).

Next, the control device 11 controls the microwave output device 16 to generate the first microwaves, and supplies the first microwaves to the processing space S in the processing chamber 12 via the antenna 18 (step S103). The first microwaves are microwaves with a power lower than that of the microwaves for plasma processing, and are microwaves (i.e., SP microwaves) including a single frequency component. The control device 11 generates the SP microwaves with a power lower than that of the microwaves for plasma processing so that plasma is not generated in the processing space S.

Next, the control device 11 controls the microwave output device 16 to start sweeping of the frequency of a single frequency component of the SP microwaves (step S104).

Next, the control device 11 measures the power of the traveling waves and the power of the transmitted waves with the measurement device 22 (step S105, measurement process). The control device 11 performs the measurement process in a state where no plasma is generated in the processing space S. The control device 11 performs the measurement process while sweeping the frequency of the single frequency component of the SP microwaves.

Next, the control device 11 calculates the resonance frequency fᵣ of the resonating structure 100 based on the frequency distribution of the transmission characteristic value (S₂₁ value) of the resonating structure 100 calculated from the power of the traveling waves and the power of the transmitted waves (step S106, calculation process). The control device 11 calculates, as the resonance frequency fᵣ of the resonating structure 100, the frequency at which the S₂₁ value of the resonating structure 100 becomes a minimum value in the frequency distribution of the transmission characteristic value (S₂₁ value) of the resonating structure 100.

The actual resonance frequency fᵣ₂ in the processing chamber 12 deviates from the resonance frequency fᵣ determined based on the design value depending on the mechanical difference and the physical property of the resonating structure 100 and the environment where the resonating structure 100 is used (see FIG. 14). Further, due to the deviation between the resonance frequency fᵣ₁ and the resonance frequency fᵣ₂, the target frequency band B1 corresponding to the resonance frequency fᵣ₁ and the target frequency band B2 corresponding to the resonance frequency fᵣ₂ deviate from each other (see FIG. 14). When the microwaves for plasma processing are generated to start plasma processing on the substrate WP in a state where the microwave frequency deviates from the target frequency band due to the change in the target frequency band, the microwaves and the resonating structure 100 do not resonate. Therefore, the microwave power is not sufficiently absorbed by the plasma, and the increase in the density of the plasma is hindered.

Hence, in the plasma processing apparatus 1 according to the present embodiment, before the plasma processing is performed in the processing chamber 12, the measurement process and the calculation process are performed to measure the resonance frequency fᵣ of the actual resonating structure 100 provided in the processing chamber 12. Accordingly, in the plasma processing apparatus 1, the resonance frequency fᵣ of the resonating structure 100 can be accurately measured without being affected by the mechanical difference of the resonating structure 100.

Next, the control device 11 determines, as the target frequency band, a predetermined frequency band higher than the resonance frequency fᵣ calculated by the calculation process in step S106 (step S107). Accordingly, in the plasma processing apparatus 1, it is possible to accurately determine the target frequency band corresponding to the resonance frequency fᵣ of the actual resonating structure 100 provided in the processing chamber 12.

Next, the supply of the processing gas into the processing chamber 12 is temporarily stopped, and the processing gas remaining in the processing chamber 12 is exhausted. Then, the gate valve G is opened, and an unprocessed substrate WP is loaded into the processing chamber 12 through the opening 12c and placed on the electrostatic chuck 14c by a robot arm (not shown) (step S108). Then, the gate valve G is closed. Next, the control device 11 opens the valve 38b, and controls the flow controller 38c such that the processing gas of a predetermined flow rate is supplied into the processing chamber 12, thereby resuming the gas supply into the processing chamber 12. Thereafter, the control device 11 controls the exhaust device 56 to adjust the pressure in the processing chamber 12.

Next, the control device 11 controls the microwave output device 16 to generate second microwaves and supply the second microwaves to the processing space S in the processing chamber 12 (step S109). The second microwaves are microwaves with a power greater than that of the first microwaves and used for plasma processing. The second microwaves may be either the SP microwaves or the BB microwaves. By supplying the second microwaves to the processing space S in the processing chamber 12, plasma of the processing gas is generated, and plasma processing of the substrate WP is started. In this case, it is assumed that the electron density of the plasma reaches the cutoff density. When the electron density of the plasma reaches the cutoff density, the microwaves cannot propagate in the processing space S in the processing chamber 12.

Therefore, during the plasma processing, the control device 11 controls the microwave output device 16 to generate the second microwaves including a frequency component in a target frequency band higher than the resonance frequency fᵣ, thereby performing a resonance process in which the second microwaves resonate with the resonating structure 100. Here, the target frequency band corresponds to the resonance frequency fᵣ of the actual resonating structure 100 provided in the processing chamber 12. Thus, by generating the second microwaves including a frequency component in a target frequency band higher than the resonance frequency fᵣ, the second microwaves can reliably resonate with the resonating structure 100. As a result, the density of the plasma can be stably increased by resonance.

In other words, due to the resonance between the second microwaves and the resonating structure 100, both the dielectric constant and the magnetic permeability of the plasma in the processing space S can become negative, and the second microwaves can propagate in the processing space S as can be seen from the above Eq. (1). As a result, in the processing space S in the processing chamber 12, the second microwaves can propagate beyond the skin depth of the plasma, and the power of the second microwaves is efficiently injected into the plasma. As a result, high-density plasma can be generated over a wide range beyond the skin depth of the plasma.

Next, the control device 11 determines whether a predetermined time has elapsed from the start of the supply of the second microwaves (step S110). Here, the predetermined time is the time from the start of the supply of the second microwaves to the completion of the plasma processing such as etching on the substrate WP. If the predetermined time has not elapsed (step S110: No), the processing shown in step S109 is performed again.

On the other hand, if the predetermined time has elapsed (step S110: Yes), the control device 11 controls the microwave output device 16 to stop the supply of the second microwaves (step S111). Then, the control device 11 closes the valve 38b to stop the supply of the processing gas into the processing chamber 12 (step S112). Next, the control device 11 controls the exhaust device 56 to exhaust the processing gas in the processing chamber 12. Thereafter, the gate valve G is opened, and the processed substrate WP is unloaded from the processing chamber 12 by a robot arm (not shown) (step S113). After the substrate WP is unloaded, the control device 11 ends a series of operations in the plasma processing apparatus 1.

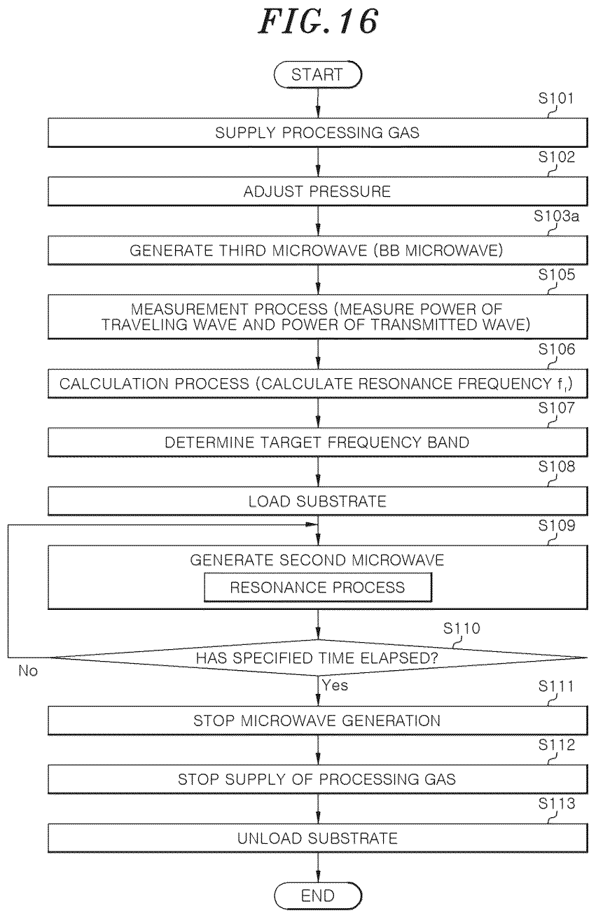

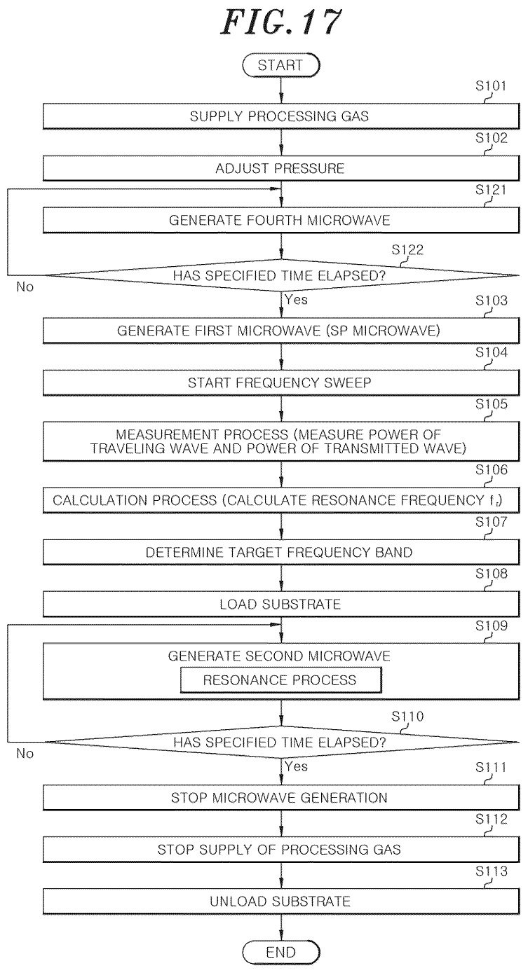

Next, the modification of the specific operation of the plasma processing apparatus 1 shown in FIG. 15 will be described with reference to FIGS. 16 and 17. FIG. 16 is a flowchart showing another example of the sequence of the processing performed by the plasma processing apparatus 1 according to the first embodiment. Further, in the processing illustrated in FIG. 16, the processes denoted by like reference numerals as those in FIG. 15 is the same as the processing described using FIG. 15 except the following description, so that detailed description thereof will be omitted.

After step S102, the control device 11 controls the microwave output device 16 to generate third microwaves, and supplies the third microwaves to the processing space S in the processing chamber 12 via the antenna 18 (step S103a). The third microwaves are microwaves (i.e., BB microwaves) with a power lower than that of the microwaves for plasma processing (i.e., the second microwaves), and are microwaves including a plurality of frequency components that belong to a predetermined frequency bandwidth. The control device 11 generates BB microwaves with a power lower than that of the microwaves for plasma processing so that plasma is not generated in the processing space S.

Next, the control device 11 measures the power of the traveling waves and the power of the transmitted waves with the measurement device 22 (step S105, measurement process). The control device 11 performs the measurement process in a state where no plasma is generated in the processing space S. Further, the control device 11 performs the measurement process for each frequency of the multiple frequency components of the BB microwaves. Then, the processes subsequent to step S106 are performed.

In accordance with the present embodiment, by using the BB microwaves, the measurement process can be performed without sweeping the frequency, and the processing speed of the plasma processing apparatus 1 can be improved.

FIG. 17 is a flowchart showing another example of the sequence of the processing performed by the plasma processing apparatus 1 according to the first embodiment. Further, in the processes illustrated in FIG. 17, the processes denoted by like reference numerals as those in FIG. 15 are the same processes as those described with reference to FIG. 15 except the following description, so that detailed description thereof will be omitted.

After step S102, the control device 11 controls the microwave output device 16 to generate fourth microwaves and supply the fourth microwaves to the processing space S in the processing chamber 12 via the antenna 18 (step S121, heating process). The fourth microwaves are microwaves with a power greater than or equal to the power of the microwaves for plasma processing (i.e., the second microwave). The fourth microwaves may be either the SP microwaves or the BB microwaves. By supplying the fourth microwaves to the processing space S in the processing chamber 12, plasma of the processing gas is generated. Then, the resonating structure 100 is heated by the generated plasma.

Next, the control device 11 determines whether a predetermined time has elapsed from the start of the heating process (step S122). Here, the predetermined time is the time from the start of the heating process to the completion of thermal expansion of each resonator in the resonating structure 100, and is measured in advance by tests or simulations. If the predetermined time has not elapsed (step S122: No), the process shown in step S121 is performed again.

On the other hand, if the predetermined time has elapsed (step S122: Yes), the control device 11 controls the microwave output device 16 to generate the first microwaves instead of the fourth microwaves (step S103). Then, the processes subsequent to step S104, including the measurement process (step S105), are performed.

By performing the heating process prior to the measurement process, the measurement process of the resonance frequency fᵣ can be performed in a state where each resonator in the resonating structure 100 is thermally expanded. Therefore, even if thermal expansion of each resonator in the resonating structure 100 occurs when the second microwaves are supplied to the processing space S in the processing chamber 12, the change in the resonance frequency fᵣ of the resonating structure 100 from the value at the time of measurement can be suppressed. As a result, in accordance with the present embodiment, the resonance frequency fᵣ of the resonating structure 100 can be measured with high accuracy while suppressing the influence of thermal expansion of each resonator in the resonating structure 100.

### Second Embodiment

In the first embodiment, the resonance frequency fᵣ is calculated using the frequency distribution of the transmission characteristic value (S₂₁ value) of the resonating structure 100. On the other hand, in the second embodiment, the resonance frequency fᵣ is calculated using the frequency distribution of a reflection characteristic value (S₁₁ value) of the resonating structure 100.

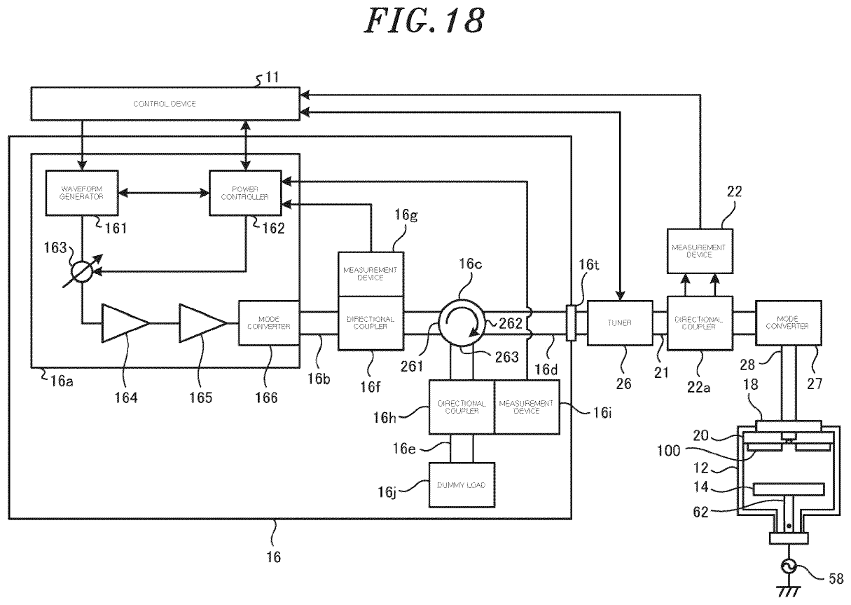

FIG. 18 shows an example of the configuration of the microwave output device 16, the measurement device 22, and the tuner 26 in the second embodiment. Further, in the configuration illustrated in FIG. 18, the components denoted by like reference numerals as those in FIG. 2 are the same components as those described with reference to FIG. 2 except the following description, so that detailed description thereof will be omitted.

In the plasma processing apparatus 1 according to the second embodiment, the measurement device 22 is connected to the waveguide 21 via the directional coupler 22a disposed in the waveguide 21. The directional coupler 22a branches a part of the microwaves (i.e., the traveling waves) traveling from the microwave output device 16 to the processing chamber 12 side, and outputs a part of the traveling waves to the measurement device 22. Further, the directional coupler 22a branches a part of the microwaves (i.e., the reflected waves) returning from the processing chamber 12 side to the output end 16t of the microwave output device 16, and outputs the part of the reflected waves to the measurement device 22. The measurement device 22 measures, for each frequency, the power of the traveling waves propagating through the waveguide 21 based on the part of the traveling waves outputted from the directional coupler 22a, and outputs the measurement result to the control device 11. Further, the measurement device 22 measures, for each frequency, the power of the reflected waves propagating through the waveguide 21 based on a part of the reflected waves outputted from the directional coupler 22a, and outputs the measurement result to the control device 11.

Here, the frequency distribution of the reflection characteristic value (S₁₁ value) of the resonating structure 100 will be described. The S₁₁ value of the resonating structure 100 is calculated by log (P3/P1), where P1 is the power of the traveling wave and P3 is the power of the reflected waves. The frequency distribution of the S₁₁ value of the resonating structure 100 is the same as the frequency distribution of the S₂₁ value of the resonating structure 100 illustrated in FIG. 13. In other words, when the frequency of the microwave supplied to the processing space S coincides with the resonance frequency fᵣ (=about 2.35 GHZ) of the resonating structure 100, the S₁₁ value of the resonating structure 100 becomes a minimum value, and the resonance between the microwave and the resonating structure 100 occurs. The resonance between the microwave and the resonating structure 100 is maintained even in a predetermined frequency band (e.g., in a range of about 0.1 GHz from the resonance frequency fᵣ) higher than the resonance frequency fᵣ of the resonating structure 100.

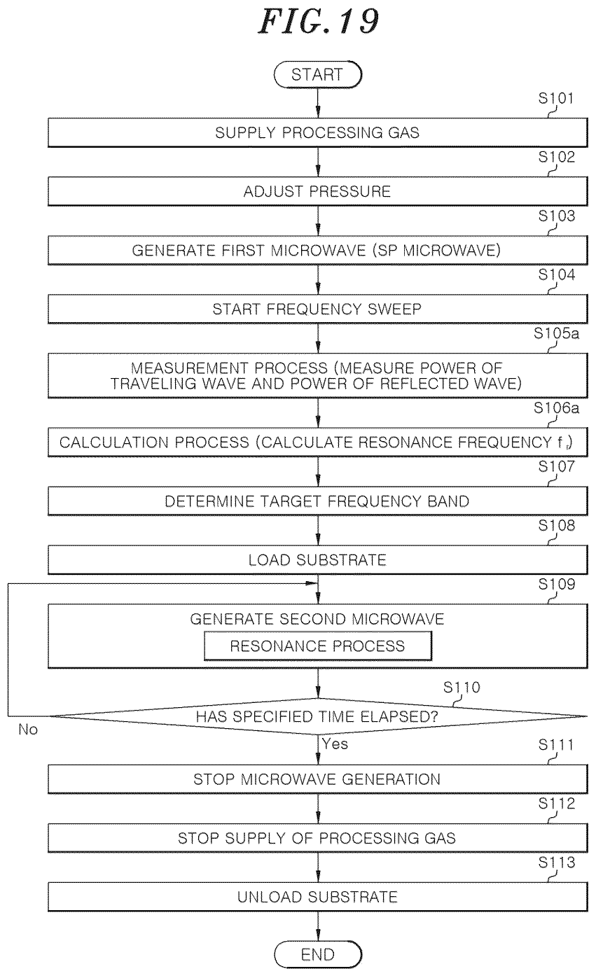

Next, a specific operation of the plasma processing apparatus 1 according to the second embodiment will be described with reference to FIG. 19. FIG. 19 is a flowchart showing an example of a sequence of processing performed by the plasma processing apparatus 1 according to the second embodiment. Further, in the processes illustrated in FIG. 19, the processes denoted by like reference numerals as those in FIG. 15 are the same processes as those described with reference to FIG. 15 except the following description, so that detailed description thereof will be omitted.

After step S104, the control device 11 measures the power of the traveling waves and the power of the reflected waves with the measurement device 22 (step S105a, measurement process). The control device 11 performs the measurement process in a state where no plasma is generated in the processing space S. The control device 11 performs the measurement process while sweeping the frequency of a single frequency component of the SP microwaves.

Next, the control device 11 calculates the resonance frequency fᵣ of the resonating structure 100 based on the frequency distribution of the reflection characteristic value (S₁₁ value) of the resonating structure 100 calculated from the power of the traveling waves and the power of the reflected waves (step S106a, calculation process). The control device 11 calculates, as the resonance frequency fᵣ of the resonating structure 100, the frequency at which the S₁₁ value of the resonating structure 100 becomes a minimum value in the frequency distribution of the reflection characteristic value (S₁₁ value) of the resonating structure 100. Then, the processes subsequent to step S107 are performed.

In this manner, in the second embodiment, the resonance frequency fᵣ is calculated using the frequency distribution of the reflection characteristic value (S₁₁ value) of the resonating structure 100. Accordingly, in the plasma processing apparatus 1, the resonance frequency fᵣ of the resonating structure 100 can be accurately measured without being affected by the mechanical difference of the resonating structure 100.

### Third Embodiment

In the first embodiment, the resonance frequency fᵣ is calculated using the frequency distribution of the transmission characteristic value (S₂₁ value) of the resonating structure 100, which is calculated from the power of the traveling waves and the power of the transmitted waves. On the other hand, in the third embodiment, the power of the scattered waves scattered laterally from the resonating structure 100 is measured, and the resonance frequency fᵣ is calculated using the frequency distribution of the transmission characteristic value (S₂₁ value) of the resonating structure 100, which is calculated from the power of the traveling waves and the power of the scattered waves.

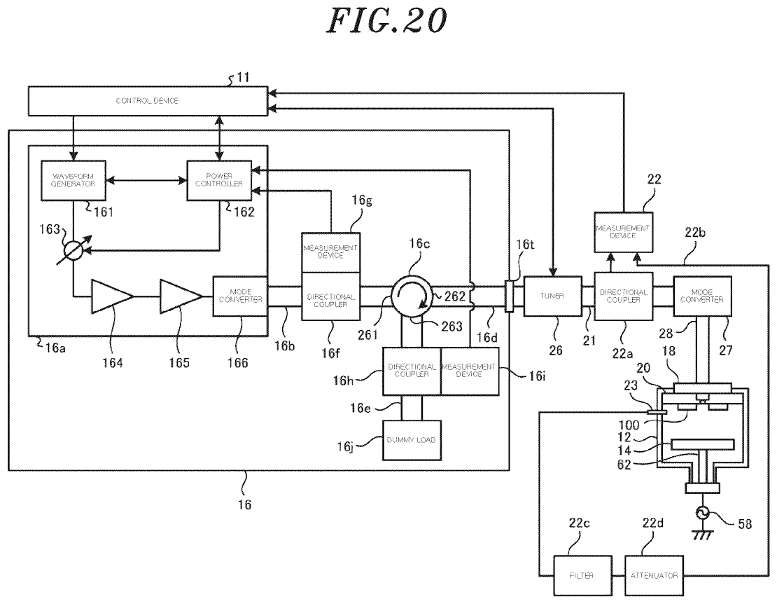

FIG. 20 shows an example of the configuration of the microwave output device 16, the measurement device 22, and the tuner 26 in the third embodiment. Further, in the configuration illustrated in FIG. 20, the components denoted by like reference numerals as those in FIG. 2 are the same components as those described with reference to FIG. 2 except the following description, so that detailed description thereof will be omitted.

In the plasma processing apparatus 1 according to the third embodiment, the measurement device 22 is connected to the waveguide 21 via the directional coupler 22a disposed in the waveguide 21. The directional coupler 22a branches a part of the microwaves (i.e., traveling waves) traveling from the microwave output device 16 toward the processing chamber 12 side, and outputs the part of the traveling waves to the measurement device 22. The measurement device 22 measures, for each frequency, the power of the traveling waves propagating through the waveguide 21 based on the part of the traveling waves outputted from the directional coupler 22a, and outputs the measurement result to the control device 11.

Further, an antenna 23 is disposed on the sidewall of the processing chamber 12, and the measurement device 22 is connected to the antenna 23 via the waveguide 22b. The antenna 23 protrudes into the processing chamber 12. The antenna 23 receives the microwaves (i.e., scattered waves) scattered laterally from the resonating structure 100. The waveguide 22b returns the scattered waves received by the antenna 23 from the processing chamber 12 side to the measurement device 22. The measurement device 22 measures, for each frequency, the power of the scattered waves scattered laterally from the resonating structure 100 based on the scattered waves returned from the waveguide 22b, and outputs the measurement results to the control device 11.

Here, the frequency distribution of the transmission characteristic value (S₂₁ value) of the resonating structure 100 will be described. The S₂₁ value of the resonating structure 100 is calculated by log (P4/P1), where P1 is the power of the traveling waves and P4 is the power of the scattered waves. The frequency distribution of the S₂₁ value of the resonating structure 100 is the same as the frequency distribution of the S₂₁ value of the resonating structure 100 illustrated in FIG. 13. In other words, when the frequency of the microwaves supplied to the processing space S coincides with the resonance frequency fᵣ (=approximately 2.35 GHZ) of the resonating structure 100, the S₂₁ value of the resonating structure 100 becomes a minimum value, and the resonance between the microwaves and the resonating structure 100 occurs. The resonance between the microwaves and the resonating structure 100 is maintained even in a predetermined frequency band (e.g., in a range of about 0.1 GHz from the resonance frequency fᵣ) higher than the resonance frequency fᵣ of the resonating structure 100.

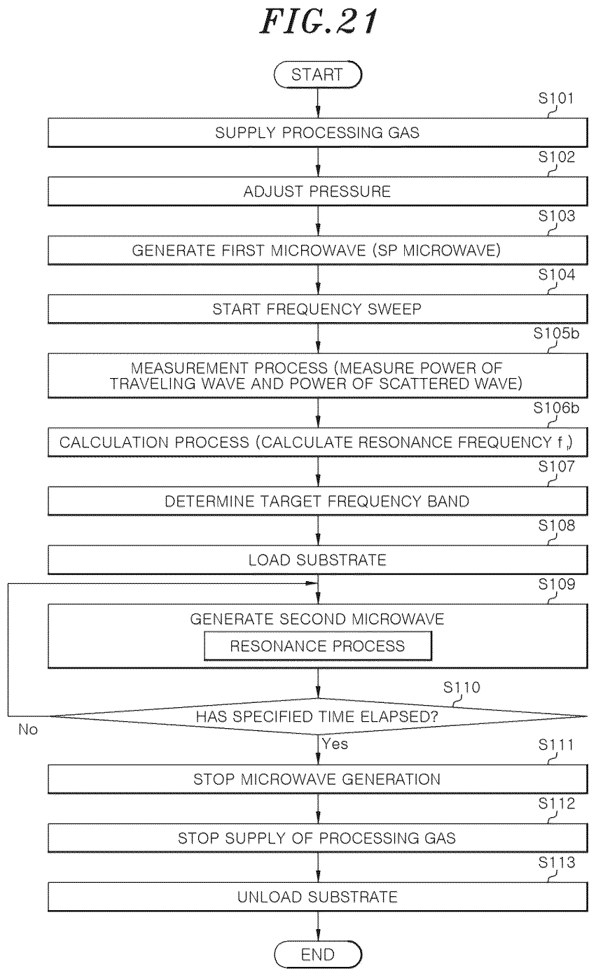

Next, the specific operation of the plasma processing apparatus 1 according to the third embodiment will be described with reference to FIG. 21. FIG. 21 is a flowchart showing an example of a sequence of processing performed by the plasma processing apparatus 1 according to the third embodiment. Further, the processes denoted by like reference numerals as those in FIG. 21 is the same as the processing described using FIG. 15 except the following description, so that detailed description thereof will be omitted.

After step S104, the control device 11 measures the power of the traveling waves and the power of the scattered waves with the measurement device 22 (step S105b, measurement process). The control device 11 performs the measurement process in a state where no plasma is generated in the processing space S. Further, the control device 11 performs the measurement process while sweeping the frequency of the single frequency component of the SP microwaves.

Next, the control device 11 calculates the resonance frequency fᵣ of the resonating structure 100 based on the frequency distribution of the transmission characteristic value (S₂₁ value) of the resonating structure 100 calculated from the power of the traveling waves and the power of the scattered waves (step S106b, calculation process). The control device 11 calculates, as the resonance frequency fᵣ of the resonating structure 100, the frequency at which the S₂₁ value of the resonating structure 100 becomes a minimum value in the frequency distribution of the transmission characteristic value (S₂₁ value) of the resonating structure 100. Then, the processes subsequent to step S107 are performed.

In this manner, in the third embodiment, the power of the scattered waves scattered laterally from the resonating structure 100 is measured, and the resonance frequency fᵣ is calculated using the frequency distribution of the transmission characteristic value (S₂₁ value) of the resonating structure 100 calculated from the power of the traveling waves and the power of the scattered waves. Accordingly, in the plasma processing apparatus 1, the resonance frequency fᵣ of the resonating structure 100 can be accurately measured without being affected by the mechanical difference of the resonating structure 100.

### OTHER MODIFICATIONS

In the above-described embodiments, the case where the measurement device 22 measures, for each frequency, the power of the traveling waves and the power of the transmitted waves, the reflected waves, or the scattered waves has been described. The present disclosure is not limited thereto, and the measurement of the power of the traveling waves may be omitted. In other words, the measurement device 22 may measure, for each frequency, the power of the transmitted waves, the reflected waves, or the scattered waves. In this case, prior to the execution of the plasma processing, the control device 11 measures the power of the transmitted waves, the reflected waves, or the scattered waves with the measurement device 22 in the measurement process. Further, the control device 11 calculates the resonance frequency fᵣ of the resonating structure 100 based on the frequency distribution of the power of the transmitted waves, the reflected waves, or the scattered waves. Specifically, the control device 11 calculates, as the resonance frequency fᵣ of the resonating structure 100, the frequency at which the power of the transmitted waves, the reflected waves, or the scattered waves becomes a minimum value in the frequency distribution of the power of the transmitted waves, the reflected waves, or the scattered waves.

Here, when the power of the traveling waves hardly changes with respect to the frequency, the frequency distribution of the power of the transmitted waves, the reflected waves, or the scattered waves is substantially the same as the frequency distribution of the transmission characteristic value (S₂₁ value) or the reflection characteristic value (S₁₁ value) of the resonating structure 100. In this case, the control device 11 can calculate the resonance frequency fᵣ using the frequency distribution of the power of the transmitted waves, the reflected waves, or the scattered waves without measuring the power of the traveling waves. Accordingly, the processing load can be reduced compared to the case of calculating the resonance frequency fᵣ using the frequency distribution of the transmission characteristic value (S₂₁ value) or the reflection characteristic value (S₁₁ value) of the resonating structure 100.

As described above, the plasma processing apparatus (e.g., plasma processing apparatus 1) according to the embodiment includes the processing chamber (e.g., the processing chamber 12), the electromagnetic wave generator (e.g., the microwave output device 16), the resonating structure (e.g., the resonating structure 100), the measurement part (e.g., the measurement device 22), and the controller (e.g., the control device 11). The processing chamber provides the processing space (e.g., the processing space S) where plasma processing is performed. The electromagnetic wave generator generates electromagnetic waves (e.g., microwaves) to be supplied to the processing space. The resonating structure is disposed in the processing chamber, and is formed by arranging the plurality of resonators (e.g., the resonators 101) capable of resonating with the magnetic field component of the electromagnetic waves and having sizes smaller than the wavelength of the electromagnetic waves. The measurement part measures, for each frequency, the power of the electromagnetic waves traveling from the electromagnetic wave generator to the resonating structure and the power of the transmitted waves, the reflected waves, or the scattered waves of the electromagnetic waves in the resonating structure. Prior to the execution of the plasma processing, the controller performs the measurement process for measuring the power of the electromagnetic waves and the power of the transmitted waves, the reflected waves, or the scattered waves with the measurement part, and the calculation process for calculating the resonance frequency (e.g., the resonance frequency fᵣ) of the resonating structure based on the frequency distribution of the characteristic value (e.g., the transmission characteristic value (S₂₁ value) or the reflection characteristic value (S₁₁ value)) of the resonating structure, which is calculated from the power of the electromagnetic waves and the power of the transmitted waves, the reflected waves, or the scattered waves. Therefore, in accordance with the plasma processing apparatus of the present embodiment, the density of the plasma can be stably increased by resonance.

Further, during the plasma processing, the controller may control the electromagnetic wave generator to generate electromagnetic waves including a frequency component in a target frequency band higher than the resonance frequency, thereby performing a resonance process in which the electromagnetic waves resonate with the resonating structure. Accordingly, high-density plasma can be generated over a wide range beyond the plasma skin depth.

Further, the controller may control the electromagnetic wave generator to generate electromagnetic waves with a power lower than that of the electromagnetic waves generated during plasma processing so that plasma is not generated in the processing space, thereby performing the measurement process in a state where no plasma is generated in the processing space. Accordingly, the measurement process can be performed without the influence of the plasma.

Further, the controller may control the electromagnetic wave generator to generate electromagnetic waves (e.g., SP microwaves) including a single frequency component, which are electromagnetic waves with a power lower than that of the electromagnetic waves generated during plasma processing, thereby performing the measurement process while sweeping the frequency of the single frequency component of the electromagnetic wave. Accordingly, the power of the electromagnetic waves and the power of the transmitted waves, the reflected waves, or the scattered waves can be quickly measured in a predetermined frequency band.

Further, the controller may control the electromagnetic wave generator to generate electromagnetic waves (e.g., BB microwaves) including a plurality of frequency components that belong to a predetermined frequency bandwidth, which are electromagnetic waves with a power lower than that of the electromagnetic waves generated during plasma processing, thereby performing the measurement process for each frequency of the multiple frequency components of the electromagnetic waves. Accordingly, the measurement process can be performed without sweeping the frequency, and the processing speed of the plasma processing apparatus can be improved.

Prior to the execution of the measurement process, the controller may control the electromagnetic wave generator to generate electromagnetic waves with a power greater than or equal to that of than that of the electromagnetic waves generated during plasma processing to produce plasma in the processing space, thereby performing the heating process for heating the resonating structure using the produced plasma. Accordingly, the resonance frequency of the resonating structure can be measured with high accuracy while suppressing the influence of thermal expansion of each resonator in the resonating structure.

The plasma processing apparatus according to the embodiment may include the waveguide (e.g., the waveguide 21) that guides the electromagnetic waves generated by the electromagnetic wave generator to the processing space. In this case, the measurement part may measure, for each frequency, the power of the electromagnetic waves propagating through the waveguide and the power of the reflected waves propagating through the waveguide. Accordingly, the power of the electromagnetic waves and the power of the reflected waves can be measured with high accuracy at a position closer to the processing space.

The resonating structure may be disposed along the first surface of the member disposed with the first surface (e.g., the bottom surface 20a) facing the processing space. Accordingly, the plasma density can be increased over a wide range by using a resonating structure located at any position in the processing chamber.

The plasma processing apparatus according to the embodiment may further include the dielectric (e.g., the a dielectric window 20) disposed with the first surface (e.g., the bottom surface 20a) facing the processing space, and the electromagnetic wave supply part (e.g., the antenna 18) for supplying the electromagnetic waves to the processing space via the dielectric. The resonating structure may be disposed along the first surface of the dielectric. Accordingly, the power of the electromagnetic waves can be efficiently absorbed by the plasma, thereby promoting the increase in the density of the plasma over a wide range.

Further, the plasma processing apparatus (e.g., the plasma processing apparatus 1) according to the embodiment includes the processing chamber (e.g., the processing chamber 12), the electromagnetic wave generator (e.g., the microwave output device 16), the resonating structure (e.g., the resonating structure 100), the measurement part (e.g., the measurement device 22), and the controller (e.g., the control device 11). The processing chamber provides the processing space (e.g., the processing space S) where plasma processing is performed. The electromagnetic wave generator generates electromagnetic waves (e.g., microwaves) to be supplied to the processing space. The resonating structure is disposed in the processing chamber, and is formed by arranging a plurality of resonators (e.g., the resonators 101) capable of resonating with the magnetic field component of the electromagnetic waves and having sizes smaller than the wavelength of the electromagnetic waves. The measurement part measures, for each frequency, the power of the transmitted waves, the reflected waves, or the scattered waves of the electromagnetic waves in the resonating structure. Prior to the execution of the plasma processing, the controller performs the measurement process for measuring the power of the transmitted waves, the reflected waves, or the scattered waves with the measurement part, and the calculation process for calculating the resonance frequency (e.g., the resonance frequency fᵣ) of the resonating structure based on the frequency distribution of the power of the transmitted waves, the reflected waves, or the scattered waves. Therefore, in accordance with the plasma processing apparatus of the embodiment, it is possible to stably increase the density of the plasma by resonance. Further, in accordance with the plasma processing apparatus of the embodiment, the processing load can be reduced compared to the case where the resonance frequency is calculated using the frequency distribution of the transmission characteristic value (S₂₁ value) or the reflection characteristic value (S₁₁ value) of the resonating structure.

While the embodiments of the present disclosure have been described, the embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

1. A plasma processing apparatus comprising:
a processing chamber that provides a processing space where plasma processing is performed;
an electromagnetic wave generator configured to generate electromagnetic waves to be supplied to the processing space;
a resonating structure disposed in the processing chamber and formed by arranging a plurality of resonators that are capable of resonating with a magnetic field component of the electromagnetic waves and have sizes smaller than a wavelength of the electromagnetic waves;
a measurement part configured to measure, for each frequency, a power of the electromagnetic waves traveling from the electromagnetic wave generator to the resonating structure and a power of transmitted waves, reflected waves, or scattered waves of the electromagnetic waves in the resonating structure; and
a controller,
wherein prior to execution of the plasma processing, the controller performs:
a measurement process for measuring the power of the electromagnetic waves and the power of the transmitted waves, the reflected waves, or the scattered waves with the measurement part, and
a calculation process for calculating a resonance frequency of the resonating structure based on frequency distribution of characteristic values of the resonating structure, which are calculated from the power of the electromagnetic waves and the power of the transmitted waves, the reflected waves, or the scattered waves.

2. The plasma processing apparatus of claim 1, wherein during the plasma processing, the controller controls the electromagnetic wave generator to generate the electromagnetic waves including a frequency component in a target frequency band higher than the resonance frequency, thereby performing a resonance process in which the electromagnetic waves resonate with the resonating structure.

3. The plasma processing apparatus of claim 1, wherein the controller controls the electromagnetic wave generator to generate electromagnetic waves with a power lower than a power of the electromagnetic waves generated during the plasma processing so that plasma is not generated in the processing space, thereby performing the measurement process in a state where no plasma is generated in the processing space.

4. The plasma processing apparatus of claim 3, wherein the controller controls the electromagnetic wave generator to generate the electromagnetic waves including a single frequency component, which are electromagnetic waves with a power lower than the power of the electromagnetic waves generated during the plasma processing, thereby performing the measurement process while sweeping the frequency of the single frequency component of the electromagnetic waves.

5. The plasma processing apparatus of claim 3, wherein the controller controls the electromagnetic wave generator to generate electromagnetic waves including a plurality of frequency components that belong to a predetermined frequency bandwidth, which are electromagnetic waves with a power lower than the power of the electromagnetic waves generated during the plasma processing, thereby performing the measurement process for each frequency of the plurality of frequency components of the electromagnetic waves.

6. The plasma processing apparatus of claim 1, wherein prior to execution of the measurement process, the controller controls the electromagnetic wave generator to generate electromagnetic waves with a power greater than or equal to the power of the electromagnetic waves generated during the plasma processing to produce plasma in the processing space, and performing a heating process for heating the resonating structure using the generated plasma.

7. The plasma processing apparatus of claim 1, further comprising:
a waveguide configured to guide the electromagnetic waves generated by the electromagnetic wave generator to the processing space,
wherein the measurement part measures, for each frequency, the power of the electromagnetic waves propagating through the waveguide and the power of the reflected waves propagating through the waveguide.

8. The plasma processing apparatus of claim 1, wherein the resonating structure is disposed along a first surface of a member disposed with the first surface facing the processing space.

9. The plasma processing apparatus of claim 8, further comprising:
a dielectric disposed with the first surface facing the processing space, and
an electromagnetic wave supply part configured to supply the electromagnetic waves to the processing space via the dielectric,
wherein the resonating structure is disposed along the first surface of the dielectric.

10. A plasma processing apparatus comprising:
a processing chamber that provides a processing space where plasma processing is performed;
an electromagnetic wave generator configured to generate electromagnetic waves to be supplied to the processing space;
a resonating structure disposed in the processing chamber and formed by arranging a plurality of resonators that are capable of resonating with a magnetic field component of the electromagnetic waves and having sizes smaller than a wavelength of the electromagnetic waves;
a measurement part configured to measure, for each frequency, a power of transmitted waves, reflected waves or scattered waves of the electromagnetic waves in the resonating structure; and
a controller,
wherein prior to execution of the plasma processing, the controller performs:
a measurement process for measuring the power of the transmitted waves, the reflected waves, or the scattered waves with the measurement part; and
a calculation process for calculating a resonance frequency of the resonating structure based on frequency distribution of the power of the transmitted waves, the reflected waves, or the scattered waves.

11. A method for measuring a resonance frequency of a resonating structure in a plasma processing apparatus,
wherein the plasma processing apparatus includes:
a processing chamber that provides a processing space where plasma processing is performed;
an electromagnetic wave generator configured to generate electromagnetic waves to be supplied to the processing space;
a resonating structure disposed in the processing chamber and formed by arranging a plurality of resonators that are capable of resonating with a magnetic field component of the electromagnetic waves and having sizes smaller than a wavelength of the electromagnetic waves; and
a measurement part configured to measure, for each frequency, a power of transmitted waves, reflected waves, or scattered waves of the electromagnetic waves in the resonating structure,
the method comprising:
measuring, prior to execution of the plasma processing, for each frequency, the power of the electromagnetic waves, and the power of the transmitted waves, the reflected waves, or the scattered waves by the measurement part; and
calculating the resonance frequency of the resonating structure based on frequency distribution of characteristic values of the resonating structure, which are calculated from the power of the electromagnetic waves and the power of the transmitted waves, the reflected waves, or the scattered waves.

12. The method of claim 11, further comprising:
controlling, during the plasma processing, the electromagnetic wave generator to generate the electromagnetic waves including a frequency component in a target frequency band higher than the resonance frequency, thereby allowing the electromagnetic waves to resonate with the resonating structure.

13. A method for measuring a resonance frequency of a resonating structure in a plasma processing apparatus,
wherein the plasma processing apparatus includes:
a processing chamber that provides a processing space where plasma processing is performed;
an electromagnetic wave generator configured to generate electromagnetic waves to be supplied to the processing space;
a resonating structure disposed in the processing chamber and formed by arranging a plurality of resonators that are capable of resonating with a magnetic field component of the electromagnetic waves and having sizes smaller than a wavelength of the electromagnetic waves; and
a measurement part configured to measure, for each frequency, a power of transmitted waves, reflected waves, or scattered waves of the electromagnetic waves in the resonating structure,
the method comprising:
measuring, prior to execution of the plasma processing, for each frequency, the power of the transmitted waves, the reflected waves, or the scattered waves by the measurement part; and
calculating the resonance frequency of the resonating structure based on frequency distribution of the power of the transmitted waves, the reflected waves, or the scattered waves.

14. The method of claim 13, further comprising:
controlling, during the plasma processing, the electromagnetic wave generator to generate the electromagnetic waves including a frequency component in a target frequency band higher than the resonance frequency, thereby allowing the electromagnetic waves to resonate with the resonating structure.
